(19) United States
(12) Patent Application Publication
(10) Pub. No.: US 2014/0041906 A1
(43) Pub. Date: Feb. 13, 2014

(54) METAL HEAT RADIATION SUBSTRATE AND MANUFACTURING METHOD THEREOF

(71) Applicant: SAMSUNG ELECTRO-MECHANICS CO., LTD., Suwon-si (KR)

(72) Inventors: Joon Seok KANG, Suwon-si (KR); Kwang Jik LEE, Suwon-si (KR); Sang Hyun SHIN, Suwon-si (KR); Hye Suk SHIN, Suwon-si (KR)

(73) Assignee: SAMSUNG ELECTRO-MECHANICS CO., LTD., Suwon-si (KR)

(21) Appl. No.: 13/960,277

(22) Filed: Aug. 6, 2013

(30) Foreign Application Priority Data
Aug. 8, 2012 (KR) 10-2012-0086752

(51) Int. Cl. H05K 1/02; H05K 3/40

(52) U.S. Cl. CPC H05K 1/0204; H05K 3/4038
USPC 174/252; 29/852

(57) ABSTRACT

Disclosed herein are a metal heat radiation substrate and a manufacturing method thereof. The metal heat radiation substrate includes: a metal substrate having a through-hole formed therein; a heat resistant insulating material filled in the through-hole and having a via hole formed at a filled portion; a metal oxide film formed on upper and lower surfaces of the metal substrate except for an inner wall of the through-hole by performing anodizing thereon; and a conductive layer filled in the via hole and formed over the metal oxide film.

### CROSS REFERENCE(S) TO RELATED APPLICATIONS

This application claims the benefit under 35 U.S.C. Section 119 of Korean Patent Application Serial No. 10-2012-0086752, entitled “Metal Heat Radiation Substrate and Manufacturing Method Thereof” filed on Aug. 8, 2012, which is hereby incorporated by reference in its entirety into this application.

### BACKGROUND OF THE INVENTION

1. Technical Field

The present invention relates to a metal heat radiation substrate and a manufacturing method thereof, and more particularly, to a metal heat radiation substrate capable of suppressing a crack and having improved thermal conductivity, and a manufacturing method thereof.

2. Description of the Related Art

Generally, one of the main problems generated when an electronic circuit is configured on a printed circuit board using an integrated circuit (IC) or an electronic component is to radiate heat from a component generating the heat. When current flows in the electronic component, the heat is inevitably generated by resistance loss. In this case, problems such as malfunction and damage are generated in the electronic component due to a temperature rise caused by the heat generation, such that a problem is generated in reliability of an electronic product.

In order to solve these problems, various heat radiation substrate structures for radiating the generated heat have been suggested. Recently, a polymer insulating layer or a ceramic insulating layer is formed on an upper surface of a metal coil using a metal member having excellent heat transfer characteristics and electrical wirings are formed on the insulating layer. For example, a through-hole is formed in the metal core, an anodized coating is formed thereon to form an insulating layer in the through-hole and on an aluminum surface, a prepreg (PPG) is then adhered to the anodized aluminum to be filled in both surfaces and the through-hole, thereby forming the insulating layer. In the through-hole filled as described above, a hole for a via is again processed, a conductive layer is formed thereon by plating, and a substrate is then manufactured. In this case, since the conductive layer is formed on the insulating layer formed on the anodized coat, the insulating layer should have high thermal conductivity in order to increase a heat radiation effect. The metal core PCB as described above has heat radiation characteristics more excellent than those of a general PCB made of a plastic material. However, since the metal core PCB uses an expensive polymer or ceramic material having relatively high thermal conductivity, it requires a high cost to manufacture the metal core PCB.

Further, in the case in which the anodizing is performed after the through-hole is formed in the aluminum substrate, volume expansion is generated on an anodized surface, such that a crack is frequently generated at a position at which the through-hole and the surface meet each other, thereby deteriorating reliability of quality. Meanwhile, in the case in which the through-hole is formed after the anodizing is performed, it is likely that a crack is generated in an aluminum oxide (Al₂O₃) film in a process of forming the through-hole due to fragile characteristics of the aluminum oxide (Al₂O₃) film.

### RELATED ART DOCUMENT

### Patent Document

(Patent Document 1) Japanese Patent Laid-Open Publication No. 10-12982 (Laid-Open Published on Jan. 16, 1998)

(Patent Document 2) Korean Patent Laid-Open Publication No. 10-2010-0125805 (Laid-Open Published on Dec. 1, 2010)

### SUMMARY OF THE INVENTION

An object of the present invention is to provide a heat radiation substrate that is capable of having improved heat radiation efficiency by directly forming a conductive layer on a surface of a metal substrate on which an oxide coat is formed to improve thermal conductivity and is capable of suppressing generation of a crack as much as possible by allowing a through-hole not to be anodized even though the through-hole is formed in the metal substrate before an anodizing process.

According to an exemplary embodiment of the present invention, there is provided a manufacturing method of a metal heat radiation substrate, the manufacturing method including: forming a through-hole in a metal substrate; filling a heat resistant insulating material in the through-hole; forming a via hole at a filled portion filled with the heat resistant insulating material; forming a metal oxide film on a metal surface by performing anodizing on the metal substrate in which the via hole is formed; and filling the via hole with a conductive material and forming a conductive layer on a surface of the metal substrate on which the metal oxide film is formed.

The manufacturing method may further include, before the filling of the via hole and the forming of the conductive layer, forming a seed layer on an inner surface of the via hole and the surface of the metal substrate on which the metal oxide surface is formed.

The manufacturing method may further include, before the forming of the seed layer, forming an adhesion layer on a surface of the metal oxide film.

The manufacturing method may further include forming a circuit pattern by removing a portion of the conductive layer formed on the surface of the metal substrate.

In the forming of the metal oxide film, the metal oxide film may be formed in a curved cross-sectional structure on a surface of a boundary portion of the metal substrate contacting the heat resistant insulating material filled in the through-hole.

The metal substrate may be an aluminum or aluminum alloy substrate.

According to another exemplary embodiment of the present invention, there is provided a manufacturing method of a metal heat radiation substrate, the manufacturing method including: forming a through-hole in a metal substrate; filling a heat resistant insulating material in the through-hole; forming a metal oxide film on a metal surface by performing anodizing the metal substrate in which the heat resistant insulating material is filled in the through-hole; forming a via hole at a portion in which the heat resistant insulating material is filled in the metal substrate on which the metal oxide film is formed; and filling the via hole with a conductive material and forming a conductive layer on a surface of the metal substrate on which the metal oxide film is formed.

The manufacturing method may further include, before the filling of the via hole and the forming of the conductive layer, forming a seed layer on an inner surface of the via hole and the surface of the metal substrate on which the metal oxide surface is formed.

The manufacturing method may further include, before the forming of the seed layer, forming an adhesion layer on a surface of the metal oxide film.

The manufacturing method may further include forming a circuit pattern by removing a portion of the conductive layer formed on the surface of the metal substrate.

In the forming of the metal oxide film, the metal oxide film may be formed in a curved cross-sectional structure on a surface of a boundary portion of the metal substrate contacting the heat resistant insulating material filled in the through-hole.

The metal substrate may be an aluminum or aluminum alloy substrate.

According to still another exemplary embodiment of the present invention, there is provided a metal heat radiation substrate including: a metal substrate having a through-hole formed therein; a heat resistant insulating material filled in the through-hole and having a via hole formed at a filled portion; a metal oxide film formed on upper and lower surfaces of the metal substrate except for an inner wall of the through-hole by performing anodizing thereon; and a conductive layer filled in the via hole and formed over the metal oxide film.

The metal heat radiation substrate may further include a seed layer formed on an inner surface of the via hole, upper and lower surfaces of the heat resistant insulating material, and a surface of the metal oxide film, and formed beneath the conductive layer.

The conductive layer formed on the metal oxide film may be a circuit pattern.

The metal oxide film may be formed in a curved cross-sectional structure at a boundary portion thereof meeting the heat resistant insulating material filled in the through-hole.

The metal substrate may be an aluminum or aluminum alloy substrate.

### BRIEF DESCRIPTION OF THE DRAWINGS

FIGS. 1A to 1F are views schematically showing a manufacturing method of a metal heat radiation substrate according to an exemplary embodiment of the present invention;

FIGS. 2A to 2F are views schematically showing a manufacturing method of a metal heat radiation substrate according to another exemplary embodiment of the present invention;

FIG. 3 is a cross-sectional view schematically showing a partial structure of a metal heat radiation substrate according to an exemplary embodiment of the present invention; and

FIG. 4 is a cross-sectional view schematically showing a metal heat radiation substrate according to another exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In the present specification, the same reference numerals will be used to describe the same components, and a detailed description thereof will be omitted in order to allow those skilled in the art to easily understand the present invention.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

The accompanying drawings referred in the present description may be ideal or abstract examples for describing exemplary embodiments of the present invention. In the accompanying drawings, a shape, a size, a thickness, and the like, may be exaggerated in order to effectively describe technical characteristics.

After a metal heat radiation substrate according to an exemplary embodiment of the present invention is described in detail with reference to the accompanying drawings, a manufacturing method thereof will be described. Here, reference numerals that are not denoted in the accompanying drawings may be reference numerals in other drawings showing the same components.

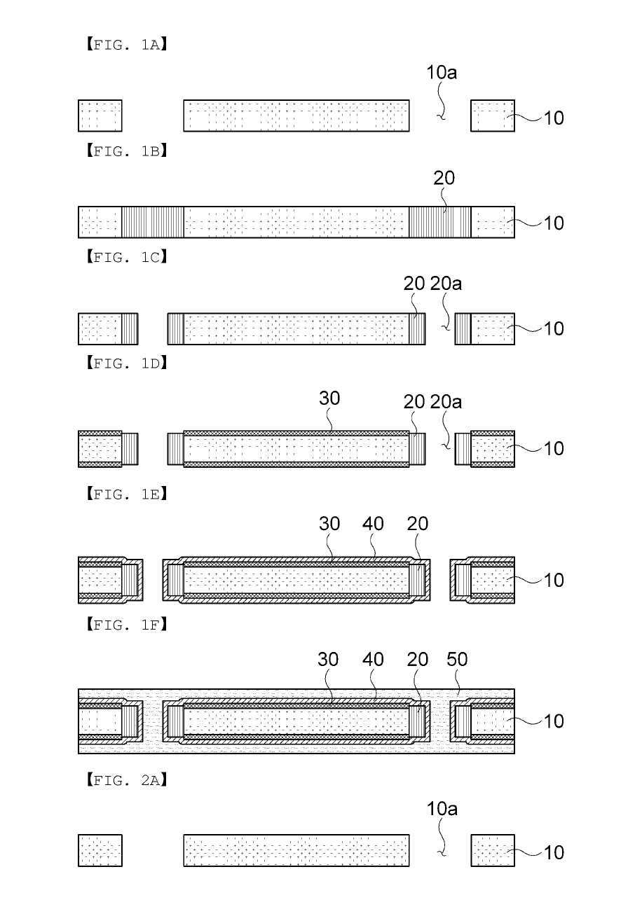

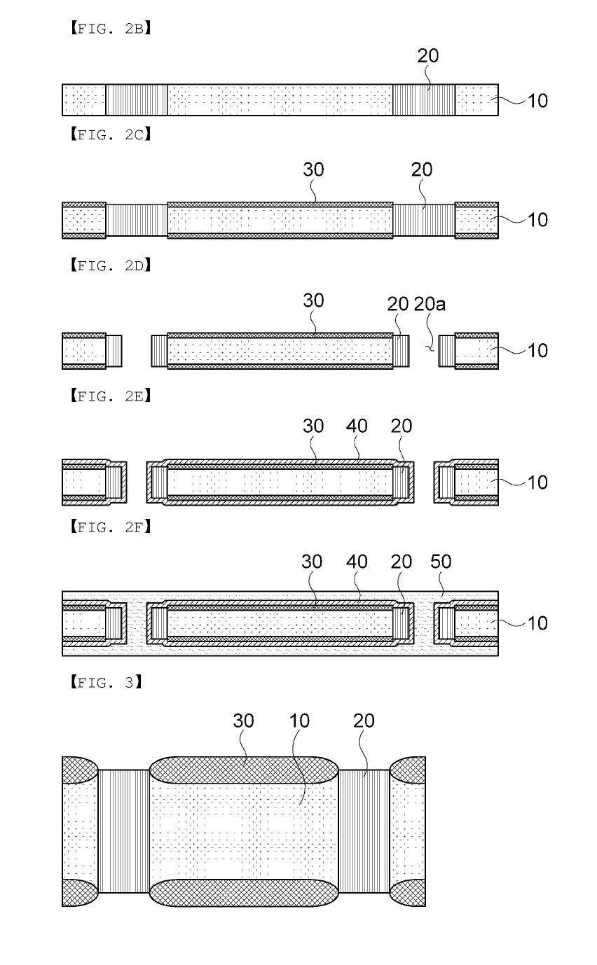

FIG. 1F is a view schematically showing a metal heat radiation substrate according to an exemplary embodiment of the present invention; FIG. 3 is a cross-sectional view schematically showing a partial structure of a metal heat radiation substrate according to an exemplary embodiment of the present invention; and FIG. 4 is a cross-sectional view schematically showing a metal heat radiation substrate according to still another exemplary embodiment of the present invention.

Referring to FIG. 1F, the metal heat radiation substrate according to the exemplary embodiment of the present invention is configured to include a metal substrate 10, a heat resistant insulating material 20, a metal oxide film 30, and a conductive layer 50. Further, as an example, as shown in FIG. 1F, the metal heat radiation substrate according to the exemplary embodiment of the present invention may further include a seed layer 40 disposed beneath the conductive layer 50.

Referring to FIG. 1F, a through-hole 10a is formed in the metal substrate 10. Here, as an example, the metal substrate 10 may be made of aluminum (Al) that has excellent heat transfer characteristics and is anodizable and an alloy thereof. The through-hole 10a in the metal substrate 10 may be formed by mechanical drilling, laser, or the like.

Next, in FIG. 1F, the heat resistant insulating material 20 is filled in the through-hole 10a of the metal substrate 10 so that a via hole 20a is formed at a filled portion. Since heat of 100° C. or more is generated due to a heat generation reaction during an anodizing process and insulation characteristics of the through-hole 10a needs to be secured in order to make electric conduction only at a required position between upper and lower surfaces of the metal substrate 10, for example, an aluminum substrate, the through-hole 10a is filled with the heat resistant insulating material 20. After the heat resistant insulating material 20 is filled in the through-hole 10a of the metal substrate 10, a through via hole 20a is formed by performing laser processing, chemical processing, or the like, on the filled portion. For example, prepreg ink may be used as the heat resistant insulating material 20. Alternatively, the via hole 20a may also be formed by applying the heat resistant insulating material 20 only to an inner wall of the through-hole 10a, that is, a boundary portion between the through-hole 10a and the metal substrate 10, for example, the aluminum substrate and allowing a central portion of the through-hole 10a to be empty.

Further, in FIG. 1F, the metal oxide film 30 is formed on upper and lower surfaces of the metal substrate 10 except for the inner wall of the through-hole 10a. That is, the metal oxide film 30 is formed on the upper and lower surfaces of the metal substrate 10, but is not formed on the inner wall of the through-hole 10a. In this case, the metal oxide film 30 is formed by anodizing the metal oxide 10. For example, after the inner wall of the through-hole 10a of the metal substrate 10 is coated or filled with the heat resistant insulating material 20, the anodizing is performed, thereby making it possible to allow the metal oxide film 30 not to be formed on the inner wall of the through-hole 10a. The metal oxide film 30 may be, for example, an aluminum oxide (Al₂O₃) film formed by anodizing the aluminum substrate.

A detailed description thereof will be provided with reference to FIG. 3. The metal oxide film 30 may be formed in a curved cross-sectional structure at a boundary portion thereof meeting the heat resistant insulating material 20 filled in the through-hole 10a of the metal substrate 10. Therefore, generation of a defect such as a crack at the boundary at which the metal oxide film 30 meets the through-hole 10a may be suppressed.

Since the metal oxide film 30 is formed in the curved structure at the boundary portion between the metal oxide film 30 and the heat resistant insulating material 20, in the case in which an adhesion layer (not shown) and/or a conductive layer seed layer 40 are formed by a sputtering or evaporation process during a process of forming the conductive layer, a sufficient film thickness may be secured as compared with the case in which the metal oxide film 30 is not formed in the curved structure, but is formed in a vertical structure.

Further, as in the related art, in the case in which the anodizing is performed after the through-hole 10a is formed in the metal substrate 10, for example, the aluminum substrate, volume expansion is generated in a process in which aluminum and oxygen are bonded to each other to become an aluminum oxide (Al₂O₃). Therefore, a crack is frequently generated due to the volume expansion generated in vertical and horizontal directions at a point at which the through-hole 10a and a surface of the aluminum substrate meet each other. However, in the exemplary embodiment of the present invention, since the anodizing is performed after the through-hole 10a is filled, the anodizing is not generated in the through-hole 10a, thereby making it possible to reduce a defective element such as a crack.

Next, in FIG. 1F, the conductive layer 50 is filled in the via hole 20a of the heat resistant insulating material 20 and is formed over the metal oxide film 30. For example, the conductive layer 50 may be formed by a plating process. In this case, the via hole 20a may be filled with a conductive material. As a material of the conductive layer 50, for example, Cu, Au, Ag, Sn, or the like, may be used. As an example, copper (Cu) may be used. The via hole 20a is filled with copper, such that electrical conductivity and thermal conductivity are improved. Further, the via hole 20a is filled with the conductive material, for example, copper, such that a conductive plugging process is removed, thereby making it possible to simplify a process. That is, although a process of forming the conductive layer 50 of the surface may be separately performed after the via hole 20a is filled with the conductive material, when plating is performed on the via hole at the time of a plating process for forming the conductive layer 50 of the surface, the process of filling the via hole 20a and the process of forming the conductive layer 50 may be performed at a time.

Further, describing another example with reference to FIG. 1F, the metal heat radiation substrate may further the seed layer 40 disposed beneath the conductive layer 50. Here, the seed layer 40 is formed beneath the conductive layer 50 and is formed on an inner surface of the via hole 20a, upper and lower surfaces of the heat resistant insulating material 20, and a surface of the metal oxide film 30. For example, in the case in which the Cu conductive layer 50 is formed, copper (Cu) may be used as a material of the seed layer 40. In order to perform electroplating on the conductive layer 50, it is required to form the seed layer 40 by a method such as an electroless plating method, a sputtering method, an evaporation method, or the like, For example, in Cu electroplating, a Cu seed layer is required.

Further, although not shown, as an example, the metal heat radiation substrate according to the exemplary embodiment may further include an adhesion layer disposed on the surface of the metal oxide film 30 in order to increase adhesion between the seed layer 40 and the metal oxide film 30. For example, in the case in which the seed layer 40 is formed by the sputtering method or the evaporation method, in order to increase adhesion between the seed layer 40 and an underlayer (the metal oxide film 30), for example, an aluminum oxide (Al₂O₃), after a material such as Ti, TiW, Ni, Cr, or the like, is thinly coated as the adhesion layer, the seed layer 40 may be formed by the sputtering method or the evaporation method in a state in which vacuum is maintained.

Further, describing another example with reference to FIG. 4, the conductive layer 50 formed on the metal oxide film 30 in the metal heat radiation substrate may be a circuit pattern 50b. For example, the circuit pattern 50b may be formed by removing a partial region of the conductive layer 50 formed on the metal oxide film 30. When the partial region of the conductive layer 50 is removed, the conductive layer 50 filled in the via hole 20a remains as a filled via hole 50a.

Next, a manufacturing method of a metal heat radiation substrate according to another exemplary embodiment of the present invention will be described with reference to the accompanying drawings. After a first exemplary embodiment of the manufacturing method of a metal heat radiation substrate is described, a second exemplary embodiment thereof will be described. Here, the metal heat radiation substrate according to the exemplary embodiment of the present invention described above and FIGS. 3 and 4 may be referred. Therefore, an overlapped description will be omitted.

FIGS. 1A to 1F are views schematically showing a manufacturing method of a metal heat radiation substrate according to an exemplary embodiment of the present invention. More specifically, FIG. 1A shows the metal substrate 10 in which the through-hole 10a is formed, FIG. 1B shows the metal substrate 10 in which the heat resistant insulating material 20 is filled in the through-hole 10a, FIG. 1C shows the metal substrate in which the via hole 20a is formed at the filled portion, FIG. 1D shows that the metal oxide film 30 is formed on a surface of the metal substrate formed in which the via hole 20a is formed, FIG. 1E shows that the seed layer 40 is formed on the metal substrate on which the metal oxide film 30 is formed, and FIG. 1F shows the metal heat radiation substrate in which the conductive layer 50 is formed on the seed layer 40.

Referring to FIGS. 1A to 1D and 1F, the manufacturing method of a metal heat radiation substrate according to the first exemplary embodiment of the present invention may include forming a through-hole (See FIG. 1A), filling an insulating material (See FIG. 1B), forming a via hole (See FIG. 1C), forming a metal oxide film (See FIG. 1D), and forming a conductive layer (See FIG. 1F). Although FIG. 1F shows the case in which the conductive layer 50 is formed on the seed layer 40, the conductive layer 50 may be formed without the seed layer 40 or be formed on the seed layer 40 as shown in FIG. 1F, according to implementations.

First referring to FIG. 1A, in the forming of the through-hole, the through-hole 10a is formed in the metal substrate 10. For example, the through-hole 10a may be formed by drilling the metal substrate 10. Here, the drilling may be mechanical drilling using a CNC drill, laser drilling using a Yag laser, a CO₂ laser, etc., chemical drilling such as etching, etc., or the like. Here, as an example, the metal substrate 10 may be made of aluminum (Al) that has excellent heat transfer characteristics and is anodizable and an alloy thereof.

For example, the case in which the through-hole 10a is formed in the aluminum substrate will be described. A contaminant such as an organic material, or the like, on a surface of the aluminum substrate is cleaned to prepare an aluminum plate. The aluminum plate has a square shape. However, the aluminum plate may also have various shapes such as a rectangular shape, a circular shape, and the like, according to a processing situation. For example, the aluminum plate may generally have a thickness of approximately 0.1 mm or more in consideration of a process and reliability of a product after the process is performed, but is not limited thereto. A size of the substrate may be changed according to process capability of a production line and configuration density of a package. A required portion of the prepared aluminum substrate is perforated to form the through-hole 10a.

Next, referring to FIG. 1B, in the filling of the insulating material, the heat resistant insulating material 20 is filled in the through-hole 10a of the metal substrate 10. Heat resistant plugging ink is filled in the through-hole 10a. For example, prepreg ink may be used.

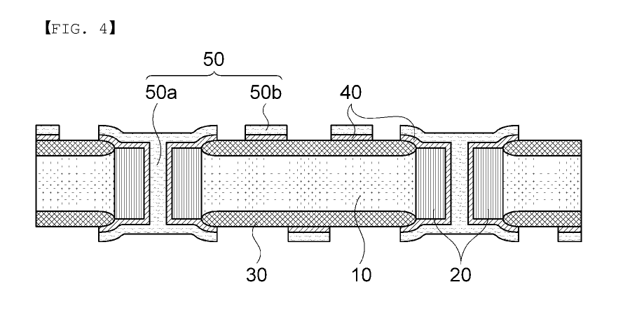

Next, referring to FIG. 1C, in the forming of the via hole, the via hole 20a is formed at the filled portion filled with the heat resistant insulating material 20. Here, the via hole 20a may be perforated and formed by laser processing using a Yag laser, a CO₂ laser, etc, chemical processing, mechanical drilling using a CNC drill, or the like. Although the case in which the via hole 20a is formed at the filled portion filled with the heat resistant insulating material 20 before an anodizing process (See FIG. 1D) is described in the present embodiment and is shown in FIG. 1C, in a manufacturing method of a metal heat radiation substrate according to another exemplary embodiment of the present invention, the via hole 20a may be formed after the anodizing process (See FIG. 2C), as shown in FIG. 2D.

Next, referring to FIG. 1D, in the forming of the metal oxide film, the anodizing is performed on the metal substrate in which the via hole 20a is formed to form the metal oxide film 30 on a metal surface. In this case, the anodizing is performed after the through-hole 10a of the metal substrate 10 is filled, such that the metal oxide film 30 is not formed on the inner wall of the through-hole 10a of the metal substrate 10. The metal oxide film 30 may be, for example, an aluminum oxide (Al₂O₃) film formed by anodizing the aluminum substrate.

The anodizing is performed on both surfaces of the metal substrate 10 in which the via hole 20a is formed to form electrical insulating layers, for example, aluminum oxide (Al₂O₃) layers in the case of the aluminum substrate, on both surfaces of the metal substrate 10. For example, when the anodizing is performed, a thickness becomes thicker than an initial thickness of the metal substrate 10 by about 20 to 40% of a thickness of the metal oxide film 30. For example, when the anodizing is performed on the aluminum substrate 10 so that an anodizing thickness is 100 μm, an aluminum oxide (Al₂O₃) layer is formed at a thickness of 60 to 80 μm at an inner portion of the aluminum substrate 10 and an aluminum oxide (Al₂O₃) layer is formed at a thickness of 20 to 40 μm at an outer portion of the aluminum substrate 10, such that the aluminum oxide (Al₂O₃) layer has a thickness of 100 μm on one surface of the aluminum substrate. That is, the entire thickness of the aluminum substrate becomes thicker by 20 to 40 μm.

Here, describing an example with reference to FIG. 3. In the forming of the metal oxide film 30, the metal oxide film 30 may be formed in a curved cross-sectional structure on a surface of a boundary portion of the metal substrate 10 contacting the heat resistant insulating material 20 filled in the through-hole 10a. Since the anodizing is not generated on the inner wall of the through-hole 10a of the metal substrate 10, the metal oxide film 30 according to the anodizing may be formed in the curved structure on the surface of the boundary portion of the metal substrate 10 contacting the heat resistant insulating material 20 filled in the through-hole 10a. Therefore, generation of a defect such as a crack at the boundary at which the metal oxide film 30 meets the through-hole 10a may be suppressed. Although FIG. 3 shows the case in which the via hole 20a is not formed at the filled portion of the heat resistant insulating material 20 filled in the through-hole 10a, as in the present embodiment, the metal oxide film 30 may be formed on the surface of the metal oxide 10 through the anodizing after the via hole is formed.

Next, referring to FIG. 1F, in the forming of the conductive layer, the via hole 20a is filled with the conductive material, and the conductive layer 50 is formed on the surface of the metal substrate on which the metal oxide film 30 is formed. For example, the conductive layer 50 may be formed by a plating process. In this case, the via hole 20a may be filled with a conductive material. As a material of the conductive layer 50, for example, Cu, Au, Ag, Sn, or the like, may be used. As an example, copper (Cu) may be used. For example, a via fill method is applied in a plating process using Cu, thereby making it possible to fill the via hole 20a with Cu. Although FIG. 1F shows the case in which the conductive layer 50 is formed on the seed layer 40, the conductive layer 50 may be formed without the seed layer 40 or be formed on the seed layer 40 as shown in FIG. 1F.

In the case in which the seed layer 40 is formed beneath the conductive layer 50 as shown in FIG. 1F, referring to FIG. 1E, as an example, the manufacturing method of a metal heat radiation substrate according to the first exemplary embodiment of the present invention may further include, before the filling of the via hole 20a and the forming of the conductive layer, forming a seed layer. In the forming of the seed layer, the seed layer 40 is formed on an inner surface of the via hole 20a and the surface of the metal substrate on which the metal oxide film 30 is formed. For example, the seed layer 40 may be formed by any one of an electroless plating method, a sputtering method, an E-beam method, and an evaporation method. For example, in the case in which the Cu conductive layer 50 is formed, copper (Cu) may be used as a material of the seed layer 40.

In addition, although not shown, the manufacturing method of a metal heat radiation substrate according to the first exemplary embodiment of the present invention may further include, before the forming of the seed layer, forming an adhesion layer. The adhesion layer, which is to increase adhesion between the metal oxide layer 30 and the seed layer 40, is formed on a surface of the metal oxide film 30. For example, the adhesion layer may be formed on the surface of the metal oxide film 30 by any one of a sputtering method, an E-beam method, and an evaporation method. Here, as a material of the adhesion layer, any one material selected from a group consisting of, for example, Ti, TiW, Ni, and Cr may be used. For example, in the case in which the seed layer 40 is formed by the sputtering method or the evaporation method, in order to increase adhesion between the seed layer 40 and an underlayer (the metal oxide film 30), for example, an aluminum oxide (Al₂O₃), after a material such as Ti, TiW, Ni, Cr, or the like, is thinly coated as the adhesion layer, the seed layer 40 may be formed by the sputtering method or the evaporation method in a state in which vacuum is maintained.

In addition, referring to FIG. 4, a manufacturing method of a metal heat radiation substrate according to another exemplary embodiment of the present invention may further include forming a circuit pattern. Referring to FIG. 4, for example, after the forming of the conductive layer of FIG. 1F, a portion of the conductive layer 50 formed on a surface of the metal substrate may be removed to form the circuit pattern 50b. A portion of the conductive layer 50 may be removed by, for example, a semi-additive method or a subtractive method to form the circuit pattern 50b. When the partial region of the conductive layer 50 is removed, the conductive layer 50 filled in the via hole 20a remains as a filled via hole 50a.

Next, a manufacturing method of a metal heat radiation substrate according to a second exemplary embodiment of the present invention will be described. Here, the metal heat radiation substrate according to the exemplary embodiment of the present invention described above, the manufacturing method of a metal heat radiation substrate according to the first exemplary embodiment of the present invention, FIGS. 1A, 1B, 1D, 1E, 1F, 3 and 4 may be referred. Therefore, an overlapped description will be omitted.

FIGS. 2A to 2F are views schematically showing a manufacturing method of a metal heat radiation substrate according to an exemplary embodiment of the present invention. More specifically, FIG. 2A shows the metal substrate 10 in which the through-hole 10a is formed, FIG. 2B shows the metal substrate 10 in which the heat resistant insulating material 20 is filled in the through-hole 10a, FIG. 2C shows that the metal oxide film 30 is formed on a surface of the metal substrate 10 in which the heat resistant insulating material 20 is filled in the through-hole 10a, FIG. 2D shows that the via hole 20a is formed at a central portion of the heat resistant insulating material 20 of the metal substrate on which the metal oxide film 30 is formed, FIG. 2E shows that the seed layer 40 is formed on the metal substrate in which the via hole 20a is formed and on which the metal oxide film 30 is formed, and FIG. 2F shows the metal heat radiation substrate in which the conductive layer 50 is formed on the seed layer 40.

Referring to FIGS. 2A to 2D and 2F, the manufacturing method of a metal heat radiation substrate according to the second exemplary embodiment of the present invention may include forming a through-hole (See FIG. 2A), filling an insulating material (See FIG. 2B), forming a metal oxide film (See FIG. 2C), forming a via hole (See FIG. 2D), and forming a conductive layer (See FIG. 2F). Although FIG. 2F shows the case in which the conductive layer 50 is formed on the seed layer 40, the conductive layer 50 may be formed without the seed layer 40 or be formed on the seed layer 40 as shown in FIG. 2F, according to implementations.

First referring to FIG. 2A, in the forming of the through-hole, the through-hole 10a is formed in the metal substrate 10. The through-hole 10a may be formed through, for example, mechanical drilling, laser drilling, chemical drilling, or the like. Here, the metal substrate 10 may be made of aluminum (Al) that has excellent heat transfer characteristics and is anodizable and an alloy thereof.

Next, referring to FIG. 2B, in the filling of the insulating material, the heat resistant insulating material 20 is filled in the through-hole 10a of the metal substrate 10. For example, prepreg ink may be used as the heat resistant insulating material 20.

Next, referring to FIG. 2C, in the forming of the metal oxide film, the anodizing is performed on the metal substrate in which the heat resistant insulating material 20 is filled in the through-hole 10a to form the metal oxide film 30 on a metal surface. In this case, the anodizing is performed after the through-hole 10a of the metal substrate 10 is filled, such that the metal oxide film 30 is not formed on the inner wall of the through-hole 10a of the metal substrate 10. The metal oxide film 30 may be, for example, an aluminum oxide (Al₂O₃) film formed by anodizing the aluminum substrate.

Here, describing an example with reference to FIG. 3. In the forming of the metal oxide film, the metal oxide film 30 may be formed in a curved cross-sectional structure on a surface of a boundary portion of the metal substrate 10 contacting the heat resistant insulating material 20 filled in the through-hole 10a. Therefore, generation of a defect such as a crack at the boundary at which the metal oxide film 30 meets the through-hole 10a may be suppressed.

Next, referring to FIG. 2D, in the forming of the via hole, the via hole 20a is formed at a portion in which the heat resistant insulating material 20 is filled in the metal substrate on which the metal oxide film 30 is formed. Here, the via hole 20a may be perforated and formed by laser processing using a Yag laser, a CO₂ laser, etc, chemical processing, mechanical drilling using a CNC drill, or the like.

Next, referring to FIG. 2F, in the forming of the conductive layer, the via hole 20a is filled with the conductive material, and the conductive layer 50 is formed on the surface of the metal substrate on which the metal oxide film 30 is formed. For example, the conductive layer 50 may be formed by a plating process. In this case, the via hole 20a may be filled with a conductive material. As a material of the conductive layer 50, for example, Cu, Au, Ag, Sn, or the like, may be used. As an example, copper (Cu) may be used.

For example, in the case in which the seed layer 40 is formed beneath the conductive layer 50 as shown in FIG. 2F, referring to FIG. 2E, the manufacturing method of a metal heat radiation substrate according to the second exemplary embodiment of the present invention may further include, before the filling of the via hole 20a and the forming of the conductive layer, forming a seed layer. In the forming of the seed layer, the seed layer 40 is formed on an inner surface of the via hole 20a and the surface of the metal substrate on which the metal oxide film 30 is formed. For example, the seed layer 40 may be formed by any one of an electroless plating method, a sputtering method, an E-beam method, and an evaporation method. For example, in the case in which the Cu conductive layer 50 is formed, copper (Cu) may be used as a material of the seed layer 40.

In addition, although not shown, the manufacturing method of a metal heat radiation substrate according to the first exemplary embodiment of the present invention may further include, before the forming of the seed layer, forming an adhesion layer. The adhesion layer may be formed on the surface of the metal oxide film 30 by any one of, for example, a sputtering method, an E-beam method, and an evaporation method in order to increase adhesion between the metal oxide film 30 and the seed layer 40. Here, as a material of the adhesion layer, any one material selected from a group consisting of, for example, Ti, TiW, Ni, and Cr may be used.

In addition, referring to FIG. 4, a manufacturing method of a metal heat radiation substrate according to another exemplary embodiment of the present invention may further include forming a circuit pattern. Referring to FIG. 4, for example, after the forming of the conductive layer of FIG. 2F, a portion of the conductive layer 50 formed on a surface of the metal substrate may be removed to form the circuit pattern 50b. A portion of the conductive layer 50 may be removed by, for example, a semi-additive method or a subtractive method to form the circuit pattern 50b.

As set forth above, according to the exemplary embodiment of the present invention, the conductive layer is directly formed on the surface of the metal substrate on which the oxide coat to improve thermal conductivity, thereby making it possible to improve the heat radiation efficiency.

In addition, the through-hole is not anodized even though the through-hole is formed in the metal substrate, for example, the aluminum substrate before the anodizing process, thereby making it possible to suppress the generation of a crack as much as possible. According to the related art, in the case in which the anodizing is performed after the through-hole is formed in the aluminum substrate, the volume expansion is generated in a process in which aluminum and oxygen are bonded to each other to become an aluminum oxide (Al₂O₃). Therefore, the crack is frequently generated due to the volume expansion generated in vertical and horizontal directions at a point at which the through-hole and the surface of the aluminum substrate meet each other. However, in the exemplary embodiment of the present invention, since the anodizing is performed after the through-hole is filled, the anodizing is not generated in the through-hole, thereby making it possible to reduce a defective element such as a crack.

In addition, the anodizing is performed after the through-hole is formed, thereby making it possible to remove a defective element such as a crack that may be generated when the through-hole penetrating through the anodized layer as in the related art is formed. In the case in which the through-hole is formed after the anodizing is performed as in the related art, it is likely that a crack is generated in an aluminum oxide (Al₂O₃) film formed by the anodizing in a process of forming the through-hole due to fragile characteristics of the aluminum oxide (Al₂O₃) film. However, according to the exemplary embodiment of the present invention, the through-hole is formed before the anodizing is performed, thereby making it possible to prevent a defect such as a crack that has been generated in the process of forming the through hole according to the related art.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains rather than limiting a scope of the present invention. In addition, exemplary embodiments according to a combination of the above-mentioned configurations may be obviously implemented by those skilled in the art. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A manufacturing method of a metal heat radiation substrate, the manufacturing method comprising:
forming a through-hole in a metal substrate;
filling a heat resistant insulating material in the through-hole;
forming a via hole at a filled portion filled with the heat resistant insulating material;
forming a metal oxide film on a metal surface by performing anodizing on the metal substrate in which the via hole is formed; and
filling the via hole with a conductive material and forming a conductive layer on a surface of the metal substrate on which the metal oxide film is formed.

2. The manufacturing method according to claim 1, further comprising, before the filling of the via hole and the forming of the conductive layer, forming a seed layer on an inner surface of the via hole and the surface of the metal substrate on which the metal oxide surface is formed.

3. The manufacturing method according to claim 2, further comprising, before the forming of the seed layer, forming an adhesion layer on a surface of the metal oxide film.

4. The manufacturing method according to claim 1, further comprising forming a circuit pattern by removing a portion of the conductive layer formed on the surface of the metal substrate.

5. The manufacturing method according to claim 1, wherein in the forming of the metal oxide film, the metal oxide film is formed in a curved cross-sectional structure on a surface of a boundary portion of the metal substrate contacting the heat resistant insulating material filled in the through-hole.

6. The manufacturing method according to claim 1, wherein the metal substrate is an aluminum or aluminum alloy substrate.

7. The manufacturing method according to claim 5, wherein the metal substrate is an aluminum or aluminum alloy substrate.

8. A manufacturing method of a metal heat radiation substrate, the manufacturing method comprising:
forming a through-hole in a metal substrate;
filling a heat resistant insulating material in the through-hole;
forming a metal oxide film on a metal surface by performing anodizing the metal substrate in which the heat resistant insulating material is filled in the through-hole;
forming a via hole at a portion in which the heat resistant insulating material is filled in the metal substrate on which the metal oxide film is formed; and
filling the via hole with a conductive material and forming a conductive layer on a surface of the metal substrate on which the metal oxide film is formed.

9. The manufacturing method according to claim 8, further comprising, before the filling of the via hole and the forming of the conductive layer, forming a seed layer on an inner surface of the via hole and the surface of the metal substrate on which the metal oxide surface is formed.

10. The manufacturing method according to claim 9, further comprising, before the forming of the seed layer, forming an adhesion layer on a surface of the metal oxide film.

11. The manufacturing method according to claim 8, further comprising forming a circuit pattern by removing a portion of the conductive layer formed on the surface of the metal substrate.

12. The manufacturing method according to claim 8, wherein in the forming of the metal oxide film, the metal oxide film is formed in a curved cross-sectional structure on a surface of a boundary portion of the metal substrate contacting the heat resistant insulating material filled in the through-hole.

13. The manufacturing method according to claim 8, wherein the metal substrate is an aluminum or aluminum alloy substrate.

14. The manufacturing method according to claim 12, wherein the metal substrate is an aluminum or aluminum alloy substrate.

15. A metal heat radiation substrate comprising:
a metal substrate having a through-hole formed therein;
a heat resistant insulating material filled in the through-hole and having a via hole formed at a filled portion;
a metal oxide film formed on upper and lower surfaces of the metal substrate except for an inner wall of the through-hole by performing anodizing thereon; and
a conductive layer filled in the via hole and formed over the metal oxide film.

16. The metal heat radiation substrate according to claim 15, further comprising a seed layer formed on an inner surface of the via hole, upper and lower surfaces of the heat resistant insulating material, and a surface of the metal oxide film, and formed beneath the conductive layer.

17. The metal heat radiation substrate according to claim 15, wherein the conductive layer formed on the metal oxide film is a circuit pattern.

18. The metal heat radiation substrate according to claim 15, wherein the metal oxide film is formed in a curved cross-sectional structure at a boundary portion thereof meeting the heat resistant insulating material filled in the through-hole.

19. The metal heat radiation substrate according to claim 15, wherein the metal substrate is an aluminum or aluminum alloy substrate.

20. The metal heat radiation substrate according to claim 18, wherein the metal substrate is an aluminum or aluminum alloy substrate.
